(19) United States
(12) Patent Application Publication
(10) Pub. No.: US 2013/0331583 A1
(43) Pub. Date: Dec. 12, 2013

(54) FUNCTIONALIZED ANTHRACENE-CAPPED OLIGOTHIOPHENES AND ORGANIC SEMICONDUCTORS BASED ON THE SAME, USE THEREOF

(71) Applicants: Wenping Hu, Beijing (CN); Huanli Dong, Beijing (CN); Huaping Zhao, Beijing (CN); Qing Meng, Beijing (CN)

(72) Inventors: Wenping Hu, Beijing (CN); Huanli Dong, Beijing (CN); Huaping Zhao, Beijing (CN); Qing Meng, Beijing (CN)

(73) Assignee: Institute of Chemistry, Chinesse Academy of Sciences

(21) Appl. No.: 13/992,502

(22) PCT Filed: Jan. 6, 2012
(86) PCT No.: PCT/CN2012/000017

§ 371 Date: Aug. 16, 2013

(30) Foreign Application Priority Data
Dec. 13, 2010 (CN) 201010613856.8

(51) Int. Cl. H01L 51/00

(52) U.S. Cl. CPC H01L 51/0068
USPC 549/59

(57) ABSTRACT

The present invention relates to a series of compounds having functionalized anthracene-capped oligothiophenes and its derivatives and the organic semiconductor device using the same, in particular, organic field-effect transistors (OFETs) comprising the above compounds.

### TECHNICAL FIELD

The present invention is generally directed to novel compounds comprising, such as ethynylene acene. More specifically, the present invention is directed to functionalized anthracene-capped oligothiophenes. The present invention also relates to organic semiconductors based on the functionalized anthracene-capped oligothiophenes and use thereof.

### BACKGROUND ART

The charge mobility of organic materials is often determined by a hopping transport process, which can be described as an electron or a hole being transferred from one molecule to the neighboring one. There are two major parameters which govern the carrier mobility: one is the electronic coupling between adjacent molecules (transfer integral), which need to be maximized; and the other is the reorganization energy, which needs to be small for efficient charge transport. It is of fundamental interest to ponder on how one can reduce the reorganization energy in a chemical system by molecular design. Generally, a higher degree of conjugation may lead to an easier charge delocalization, and then to a lower reorganization energy. Increasing the number of aryl groups is beneficial to the improvement of the degree of conjugation, but also increases the HOMO energy levels at the same time. The increasing HOMO energy levels will reduce the stability of the materials. Accordingly, we hope, through optimal molecular design, to improve the semiconducting performance of materials by way of increasing the degree of conjugation without any changes on the conjugated length of molecules.

Anthracene and oligothiophenes are widely used as the conjugation units in organic semiconductors due to their strong intermolecular interactions. Incorporation of the two kinds of functional groups may be an effective way toward the high-performance organic semiconductors. Most oligothiophene-based organic semiconductors are σ-bond linked compounds and exhibit lower device performance due to their non-planar structures resulted from the steric repulsion between the adjacent aromatic rings. If carbon-carbon triple bonds are introduced to replace a-bonds, the steric repulsion between the adjacent aromatic rings will be eliminated.

Therefore, in order to obtain an improved compound suitable in organic semiconductors, the inventor surprisingly found a new organic semiconductor comprising functionalized anthracene-capped oligothiophenes wherein anthracene and oligothiophenes are linked with carbon-carbon bonds through Sonogashira coupling reaction. The replacement of σ-bond with carbon-carbon bonds is also helpful to improve the degree of conjugation and then will lower the reorganization energy. The inventive molecules can form more regularly linear structure and will result in the more close packing structure in the solid state, which will be in favor of intermolecular charge transfer. Specially, the inventive anthracene units linked through 9-position instead of 2-position will increase the degree of conjugation of the molecule along the direction perpendicular to the long axis of the molecule but without increasing the conjugated length of the whole molecule, and therefore will improve the stability of the materials. Moreover, the π-π stacking between anthracene groups will also be helpful to the intermolecular stacking in the solid state.

### DISCLOSURE OF THE INVENTION

The present invention has been made with a view to solving the above problems in prior art, and an object of the present invention is to provide new compounds having functionalized anthracene-capped oligothiophenes and its derivatives and organic semiconductors using the same, in particular, the organic field-effect transistors (OFETs) having the above compounds. The inventors have found that the object can be achieved with the utilization of new compounds having functionalized anthracene-capped group and its derivatives having a specific structure represented by the following general formula (I).

That is, the present invention provides new compounds having functionalized anthracene-capped group and its derivatives represented by the following general formula (I): Compounds represented by the following general formula (I):

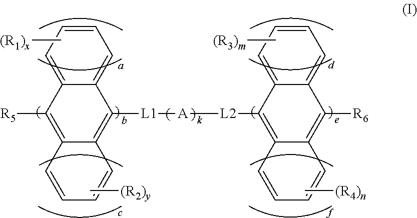

Wherein, R1, R2, R3, R4, R5 and R6, identical or different from each other, each independently represent
a hydrogen atom,
a substituted or unsubstituted alkyl group having 1 to 50 carbon atoms,
a substituted or unsubstituted alkoxyl group having 1 to 50 carbon atoms,
a substituted or unsubstituted aryl group having 6 to 50 carbon atoms,
a substituted or unsubstituted cycloalkyl group having 3 to 50 carbon atoms,
a substituted or unsubstituted heteroaromatic group having 5 to 50 carbon atoms, wherein heteroatoms Z are selected from the group consisting of the elements of IIIA, IVA, VA or VIA in periodic table of elements, such as B, Si, Sn, N, O, S, Se,
a substituted or unsubstituted heteroaryl having 5 to 50 carbon atoms,
a substituted or unsubstituted aralkyl group, wherein the aryl portion has 6 to 50 carbon atoms and the alkyl portion has 1 to 50 carbon atoms,
a substituted or unsubstituted aryloxy group having 5 to 50 carbon atoms;

L1, L2, identical or different, represent single bond, double bond or triple bond,

A represents a heteroaromatic group, wherein heteroatom W are selected from the group consisting of the elements of IIIA, IVA, VA or VIA in periodic table of elements, such as B, Si, Sn, N, O, S, Se;

a, c, d, f, identical or different from each other, represent an integer of 1-10;

b, e, identical or different from each other, represent an integer of 1-5;

k represents an integer of 1-5;

x, y, m, n, identical or different, represent an integer of between 0 and the number of rings, for example, 1-10;

Provided that, when b is 1, R5- is hydrogen; when e is 1, -R6 is hydrogen; when all of a, c, d and f equal to 1, A is not

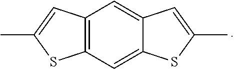

According to one embodiment, in formula (I), the elements of IIIA, IVA, VA or VIA in periodic table of elements are selected from B, Si, Sn, N, O, S and Se.

According to another embodiment, in formula (I), wherein R1, R2, R3, R4, R5 and R6, identical or different from each other, each independently represent
a hydrogen atom,
a substituted or unsubstituted alkyl group having 1 to 6 carbon atoms,
a substituted or unsubstituted alkoxyl group having 1 to 6 carbon atoms,
a substituted or unsubstituted aryl group having 6 to 8 carbon atoms,
a substituted or unsubstituted cycloalkyl group having 3 to 8 carbon atoms,
a substituted or unsubstituted heteroaromatic group having 5 to 8 carbon atoms, wherein heteroatoms Z are selected from the group consisting of B, Si, Sn, N, O, S, Se,
a substituted or unsubstituted heteroaryl having 5 to 10 carbon atoms,
a substituted or unsubstituted aralkyl group, wherein the aryl portion has 6 to 8 carbon atoms and the alkyl portion has 1 to 6 carbon atoms,
a substituted or unsubstituted aryloxy group having 6 to 8 carbon atoms.

According to another embodiment, in formula (I), wherein A represents a heteroaromatic group having 5-10 members, wherein heteroatom W are selected from the group consisting of the elements of IIIA, IVA, VA or VIA in periodic table of elements, such as B, Si, Sn, N, O, S, Se.

According to another embodiment, in formula (I), wherein R5 and R6, identical or different from each other, each independently represent a hydrogen atom.

According to another embodiment, in formula (I), wherein b and e represent 1 or 2.

According to another embodiment, in formula (I), wherein k equal to 1 or 2.

According to another embodiment, in formula (I), wherein L1 and L2, identical or different from each other, represent triple bond.

According to another embodiment, in formula (I), wherein W and Z, identical or different from each other, represents S or Se.

According to another embodiment, in formula (I), wherein the substituent substituting for each group in each of the general formula (I) include:
an alkyl group, such as methyl, ethyl, isopropyl, t-butyl, n-octyl, n-decyl, or n-hexadecyl; a cycloalkyl group, such as cyclopropyl, cyclopentyl, or cyclohexyl;
an alkenyl group, such as vinyl, allyl, 2-butenyl, or 3-pentenyl;
an alkynyl group, such as propargyl or 3-pentynyl,
an aryl group, such as phenyl, p-methylphenyl, naphthyl, or anthranyl;
an amino group, such as amino, methylamino, dimethylamino, diethylamino, dibenzylamino, diphenylamino, or ditolylamino;
an alkoxy group, such as methoxy, ethoxy, butoxy, or 2-ethylhexyloxy;
an aryloxy group, such as phenyloxy, 1-naphthyloxy, or 2-naphthyloxy;
an heteroaryloxy group, such as pyridyloxy, pyrazyloxy, pyrimidyloxy, or quinolyloxy;
an acyl group, such as acetyl, benzoyl, formyl, or pivaloyl;
an alkoxycarbonyl group, such as methoxycarbonyl or ethoxycarbonyl;
an aryloxycarbonyl group, such as phenyloxycarbonyl;
an acyloxy group, such as acetoxy or benzoyloxy;
an acylamino group, such as acetylamino or benzoylamino;
an alkoxycarbonylamino group, such as methoxycarbonylamino;
an aryloxycarbonylamino group, such as phenyloxycarbonylamino;
a sulfonylamino group, such as methanesulfonylamino or benzenesulfonylamino;
a sulfamoyl group, such as sulfamoyl, methylsulfamoyl, dimethylsulfamoyl, or phenylsulfamoyl;
a carbamoyl group, such as carbamoyl, methylcarbamoyl, diethylcarbamoyl, or phenylcarbamoyl;
an alkylthio group, such as methylthio or ethylthio;
an arylthio group, such as phenylthio;
a heteroarylthio group, such as pyridylthio, 2-benzimizolylthio, 2-benzoxazolylthio, or 2-benzthiazolylthio;
a sulfonyl group, such as mesyl or tosyl;
a sulfinyl group, such as methanesulfinyl or benzenesulfinyl;
a ureido group, such as ureido, methylureido, or phenylureido;
a phosphoric acid amide group;
a hydroxyl group;
a mercapto group;
a halogen atom, such as a fluorine atom, a chlorine atom, a bromine atom, or an iodine atom;
a cyano group;
a sulfo group;
a carboxyl group;
a nitro group;
a hydroxamic acid group;
a sulfino group; a hydrazino group;
an imino group; a heterocyclic group containing, as a hetero atom, for example, a nitrogen atom, an oxygen atom, or a sulfur atom, and specific examples include imidazolyl, pyridyl, quinolyl, furyl, thienyl, piperidyl, morpholino, benzoxazolyl, benzimidazolyl, and benzthiazolyl; and
a silyl group, such as trimethylsilyl or triphenylsilyl.

According to another embodiment, in formula (I), for example, they are:

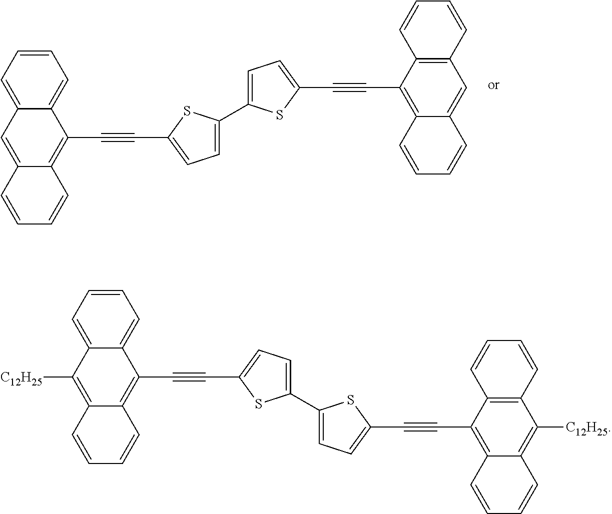

Examples of aryl group used in the formula (I) include, but not limit to, a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-l-naphthyl group, a 4-methyl-I -anthryl group, a 4′-methylbiphenylyl group, a 4″-t-butyl-p-terphenyl-4-yl group, a 9,9-dimethylfluorene-1-yl group, a 9,9-dimethylfluorene-2-yl group, a 9,9-dimethylfluorene-3-yl group, and a 9,9-dimethylfluorene-4-yl group. Further examples include a substituent which is a combination of a phenyl group, a phenylene group, a naphthyl group, and a napthalene group (such as a phenylnaphthyl group, a naphthylphenyl group, a naphthylnaphthyl group, a naphthylnaphthylnaphthyl group, a phenylphenylnaphthyl group, a naphthylnaphthylphenyl group, a naphthylphenylnaphthyl group, a naphthylphenylphenyl group, a phenylnaphthylnaphthyl group, and a phenylnaphthylphenyl group). A group derived from a substituted or unsubstituted aryl group having 6 to 8 carbon atoms is preferred. In particular, a phenyl, naphthyl group and phenanthryl group are preferred.

Examples of the heteroaryl group used in the formula (I) include, but not limit to, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthrolin-2-yl group, a 1,7-phenanthrolin-3-yl group, a 1,7-phenanthrolin-4-yl group, a 1,7-phenanthrolin-5-yl group, a 1,7-phenanthrolin-6-yl group, a 1,7-phenanthrolin-8-yl group, a 1,7-phenanthrolin-9-yl group, a 1,7-phenanthrolin-10-yl group, a 1,8-phenanthrolin-2-yl group, a 1,8-phenanthrolin-3-yl group, a 1,8-phenanthrolin-4-yl group, a 1,8-phenanthrolin-5-yl group, a 1,8-phenanthrolin-6-yl group, a 1,8-phenanthrolin-7-yl group, a 1,8-phenanthrolin-9-yl group, a 1,8-phenanthrolin-10-yl group, a 1,9-phenanthrolin-2-yl group, a 1,9-phenanthrolin-3-yl group, a 1,9-phenanthrolin-4-yl group, a 1,9-phenanthrolin-5-yl group, a 1,9-phenanthrolin-6-yl group, a 1,9-phenanthrolin-7-yl group, a 1,9-phenanthrolin-8-yl group, a 1,9-phenanthrolin-10-yl group, a 1,10-phenanthrolin-2-yl group, a 1,10-phenanthrolin-3-yl group, a 1, 10-phenanthrolin-4-yl group, a 1, 10-phenanthrolin-5-yl group, a 2,9-phenanthrolin- 1-yl group, a 2,9-phenanthrolin-3-yl group, a 2,9-phenanthrolin-4-yl group, a 2,9-phenanthrolin-5-yl group, a 2,9-phenanthrolin-6-yl group, a 2,9-phenanthrolin-7-yl group, a 2,9-phenanthrolin-8-yl group, a 2,9-phenanthrolin-10-yl group, a 2,8-phenanthrolin- 1 -yl group, a 2,8-phenanthrolin-3-yl group, a 2,8-phenanthrolin-4-yl group, a 2,8-phenanthrolin-5-yl group, a 2,8-phenanthrolin-6-yl group, a 2,8-phenanthrolin-7-yl group, a 2,8-phenanthrolin-9-yl group, a 2,8-phenanthrolin-10-yl group, a 2,7-phenanthrolin-1-yl group, a 2,7-phenanthrolin-3-yl group, a 2,7-phenanthrolin-4-yl group, a 2,7-phenanthrolin-5-yl group, a 2,7-phenanthrolin-6-yl group, a 2,7-phenanthrolin-8-yl group, a 2,7-phenanthrolin-9-yl group, a 2,7-phenanthrolin-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienylgroup, a 2-methylpyrrol-1-ylgroup, a 2-methylpyrrol-3-yl group, a 2-methylpyrrol-4-yl group, a 2-methylpyrrol-5 -yl group, a 3 -methylpyrrol- 1 -yl group, a 3 -methylpyrrol-2-yl group, a 3-methylpyrrol-4-yl group, a 3-methylpyrrol-5-yl group, a 2-t-butylpyrrol-4-yl group, a 3-(2-phenylpropyl)pyrrol-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t- butyl-1-indolyl group, a 2-t-butyl-3-indolyl group, and a 4-t- butyl-3-indolyl group. Examples of the alkyl group used in the formula (I) include, but not limit to, a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1, 2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, and a 1,2,3-trinitropropyl group.

Examples of the cycloalkyl group used in the formula (I) include, but not limit to, a cyclopropyl group, a cyclobutyl group, a cyclopentyl group, a cyclohexyl group, a 4-methylcyclohexyl group, a 1-adamantyl group, a 2-adamantyl group, a 1-norbornyl group, and a 2-norbornyl group.

Examples of the alkoxyl group used in the formula (I) include, but not limit to, the alkyl portion has the same meaning of the above definition of alkyl, a methyloxy group, an ethyloxy group, a propyloxy group, an isopropyloxy group, an n-butyloxy group, an s-butyloxy group, an isobutyloxy group, a t-butyloxy group, an n-pentyloxy group, an n-hexyloxy group, an n-heptyloxy group, an n-octyloxy group, a hydroxymethyloxy group, a 1-hydroxyethyloxy group, a 2-hydroxyethyloxy group, a 2-hydroxyisobutyloxy group, a 1, 2-dihydroxyethyloxy group, a 1,3-dihydroxyisopropyloxy group, a 2,3-dihydroxy-t-butyloxy group, a 1,2,3-trihydroxypropyloxy group, a chloromethyloxy group, a 1-chloroethyloxy group, a 2-chloroethyloxy group, a 2-chloroisobutyloxy group, a 1,2-dichloroethyloxy group, a 1,3-dichloroisopropyloxy group, a 2,3-dichloro-t-butyloxy group, a 1,2,3-trichloropropyloxy group, a bromomethyloxy group, a 1-bromoethyloxy group, a 2-bromoethyloxy group, a 2-bromoisobutyloxy group, a 1,2-dibromoethyloxy group, a 1,3-dibromoisopropyloxy group, a 2,3-dibromo-t-butyloxy group, a 1,2,3-tribromopropyloxy group, an iodomethyloxy group, a 1-iodoethyloxy group, a 2-iodoethyloxy group, a 2-iodoisobutyloxy group, a 1,2-diiodoethyloxy group, a 1,3-diiodoisopropyloxy group, a 2,3-diiodo-t-butyloxy group, a 1,2,3-triiodopropyloxy group, an aminomethyloxy group, a 1-aminoethyloxy group, a 2-aminoethyloxy group, a 2-aminoisobutyloxy group, a 1,2-diaminoethyloxy group, a 1,3-diaminoisopropyloxy group, a 2,3-diamino-t-butyloxy group, a 1,2,3-triaminopropyloxy group, a cyanomethyloxy group, a 1-cyanoethyloxy group, a 2-cyanoethyloxy group, a 2-cyanoisobutyloxy group, a 1,2-dicyanoethyloxy group, a 1,3-dicyanoisopropyloxy group, a 2,3-dicyano-t-butyloxy group, a 1,2,3-tricyanopropyloxy group, a nitromethyloxy group, a 1-nitroethyloxy group, a 2-nitroethyloxy group, a 2-nitroisobutyloxy group, a 1,2-dinitroethyloxy group, a 1,3-dinitroisopropyloxy group, a 2,3-dinitro-t-butyloxy group, and a 1,2,3-trinitropropyloxy group..

Examples of the aralkyl group used in the formula (I) include, but not limit to, a benzyl group, a 1-phenylethyl group, a 2-phenylethyl group, a 1-phenylisopropyl group, a 2-phenylisopropyl group, a phenyl-t-butyl group, an [alpha]-naphthylmethyl group, a 1-[alpha]-naphthylethyl group, a 2-[alpha]-naphthylethyl group, a 1-[alpha]-naphthylisopropyl group, a 2-[alpha]naphthylisopropyl group, a [beta]-naphthylmethyl group, a 1-[beta]naphthylethyl group, a 2-[beta]-naphthylethyl group, a 1-[beta]naphthylisopropyl group, a 2-[beta]-naphthylisopropyl group, a 1-pyrrolylmethyl group, a 2-(1-pyrrolyl)ethyl group, a p-methylbenzyl group, an m-methylbenzyl group, an o-methylbenzyl group, a p-chlorobenzyl group, an m-chlorobenzyl group, an o-chlorobenzyl group, a p-bromobenzyl group, an m-bromobenzyl group, ano-bromobenzylgroup, ap-iodobenzylgroup, an m-iodobenzylgroup, an o-iodobenzyl group, a p-hydroxybenzyl group, an m-hydroxybenzyl group, an o-hydroxybenzyl group, a p-aminobenzyl group, an m-aminobenzyl group, an o-aminobenzyl group, a p-nitrobenzyl group, an m-nitrobenzyl group, an o-nitrobenzyl group, a p-cyanobenzyl group, an m-cyanobenzyl group, an o-cyanobenzyl group, a 1-hydroxy-2-phenylisopropyl group, and a 1-chloro-2-phenylisopropyl group.

Examples of the aryloxy group used in the formula (I) include, but not limit to, a phenyloxy group, a 1-naphthyloxy group, a 2-naphthyloxy group, a 1-anthryloxy group, a 2-anthryloxy group, a 9-anthryloxy group, a 1-phenanthryloxy group, a 2-phenanthryloxy group, a 3-phenanthryloxy group, a 4-phenanthryloxy group, a 9-phenanthryloxy group, a 1-naphthacenyloxy group, a 2-naphthacenyloxy group, a 9-naphthacenyloxy group, a 1-pyrenyloxy group, a 2-pyrenyloxy group, a 4-pyrenyloxy group, a 2-biphenyloxy group, a 3-biphenylyloxy group, a 4-biphenyloxy group, a p-terphenyl-4-yloxy group, a p-terphenyl-3-yloxy group, a p-terphenyl-2-yloxy group, an m-terphenyl-4-yloxy group, an m-terphenyl-3-yloxy group, an m-terphenyl-2-yloxy group, an o-tolyloxy group, an m-tolyloxy group, a p-tolyloxy group, a p-t-butylphenyloxy group, a p-(2-phenylpropyl)phenyloxy group, a 3-methyl-2-naphthyloxy group, a 4-methyl- 1 -naphthyloxy group, a 4-methyl-1-anthryloxy group, a 4′-methylbiphenylyloxy group, a 4″-t-butyl-p-terphenyl-4-yloxy group, a 9 ,9 -dimethylfluorene- 1 -yloxy group, a 9,9 -dimethylfluorene-2-yloxy group, a 9,9-dimethylfluorene-3-yloxy group, and a 9,9-dimethylfluorene-4-yloxy group.

Examples of the heteroaromatic group used in the formula (I) include, but not limit to, thiophene, imidazolyl, pyridyl, quinolyl, furyl, thienyl, piperidyl, morpholino, benzoxazolyl, benzimidazolyl, benzothiophene, and benzthiazolyl. Each of those substituents may be additionally substituted.

Examples of the substituent further substituting for each group in each of the general formula (I) include: an alkyl group (having preferably 1 to 30, more preferably 1 to 20, or particularly preferably 1 to 10 carbon atoms such as methyl, ethyl, isopropyl, t-butyl, n-octyl, n-decyl, or n-hexadecyl); a cycloalkyl group (having preferably 3 to 30, more preferably 3 to 20, or particularly preferably 3 to 10 carbon atoms, such as cyclopropyl, cyclopentyl, or cyclohexyl); an alkenyl group (having preferably 2 to 30, more preferably 2 to 20, or particularly preferably 2 to 10 carbon atoms, such as vinyl, allyl, 2-butenyl, or 3-pentenyl); an alkynyl group (having preferably 2 to 30, more preferably 2 to 20, or particularly preferably 2 to 10 carbon atoms, such as propargyl or 3-pentynyl), an aryl group (having preferably 6 to 30, more preferably 6 to 20, or particularly preferably 6 to 12 carbon atoms, such as phenyl, p-methylphenyl, naphthyl, or anthranyl); an amino group (having preferably 0 to 30, more preferably 0 to 20, or particularly preferably 0 to 10 carbon atoms, such as amino, methylamino, dimethylamino, diethylamino, dibenzylamino, diphenylamino, or ditolylamino); an alkoxy group (having preferably 1 to 30, more preferably 1 to 20, or particularly preferably 1 to 10 carbon atoms, such as methoxy, ethoxy, butoxy, or 2-ethylhexyloxy); an aryloxy group (having preferably 6 to 30, more preferably 6 to 20, or particularly preferably 6 to 12 carbon atoms, such as phenyloxy, 1-naphthyloxy, or 2-naphthyloxy); an heteroaryloxy group (having preferably 1 to 30, more preferably 1 to 20, or particularly preferably 1 to 12 carbon atoms, such as pyridyloxy, pyrazyloxy, pyrimidyloxy, or quinolyloxy); an acyl group (having preferably 1 to 30, more preferably 1 to 20, or particularly preferably 1 to 12 carbon atoms, such as acetyl, benzoyl, formyl, or pivaloyl); an alkoxycarbonyl group (having preferably 2 to 30, more preferably 2 to 20, or particularly preferably 2 to 12 carbon atoms, such as methoxycarbonyl or ethoxycarbonyl); an aryloxycarbonyl group (having preferably 7 to 30, more preferably 7 to 20, or particularly preferably 7 to 12 carbon atoms, such as phenyloxycarbonyl); an acyloxy group (having preferably 2 to 30, more preferably 2 to 20, or particularly preferably 2 to 10 carbon atoms, such as acetoxy or benzoyloxy); an acylamino group (having preferably 2 to 30, more preferably 2 to 20, or particularly preferably 2 to 10 carbon atoms, such as acetylamino or benzoylamino); an alkoxycarbonylamino group (having preferably 2 to 30, more preferably 2 to 20, or particularly preferably 2 to 12 carbon atoms, such as methoxycarbonylamino); an aryloxycarbonylamino group (having preferably 7 to 30, more preferably 7 to 20, or particularly preferably 7 to 12 carbon atoms, such as phenyloxycarbonylamino); a sulfonylamino group (having preferably 1 to 30, more preferably 1 to 20, or particularly preferably 1 to 12 carbon atoms, such as methanesulfonylamino or benzenesulfonylamino); a sulfamoyl group (having preferably 0 to 30, more preferably 0 to 20, or particularly preferably 0 to 12 carbon atoms, such as sulfamoyl, methylsulfamoyl, dimethylsulfamoyl, or phenylsulfamoyl); a carbamoyl group (having preferably 1 to 30, more preferably 1 to 20, or particularly preferably 1 to 12 carbon atoms, such as carbamoyl, methylcarbamoyl, diethylcarbamoyl, or phenylcarbamoyl); an alkylthio group (having preferably 1 to 30, more preferably 1 to 20, or particularly preferably 1 to 12 carbon atoms, such as methylthio or ethylthio); an arylthio group (having preferably 6 to 30, more preferably 6 to 20, or particularly preferably 6 to 12 carbon atoms, such as phenylthio); a heteroarylthio group (having preferably 1 to 30, more preferably 1 to 20, or particularly preferably 1 to 12 carbon atoms, such as pyridylthio, 2-benzimizolylthio, 2-benzoxazolylthio, or 2-benzthiazolylthio); a sulfonyl group (having preferably 1 to 30, more preferably 1 to 20, or particularly preferably 1 to 12 carbon atoms, such as mesyl or tosyl); a sulfinyl group (having preferably 1 to 30, more preferably 1 to 20, or particularly preferably 1 to 12 carbon atoms, such as methanesulfinyl or benzenesulfinyl); a ureido group (having preferably 1 to 30, more preferably 1 to 20, or particularly preferably 1 to 12 carbon atoms, such as ureido, methylureido, or phenylureido); a phosphoric acid amide group (having preferably 1 to 30, more preferably 1 to 20, or particularly preferably 1 to 12 carbon atoms, such as diethylphosphoric acid amide or phenylphosphoric acid amide); a hydroxyl group; a mercapto group; a halogen atom (such as a fluorine atom, a chlorine atom, a bromine atom, or an iodine atom); a cyano group; a sulfo group; a carboxyl group; a nitro group; a hydroxamic acid group; a sulfino group; a hydrazino group; an imino group; a heterocyclic group (having preferably 1 to 30 or more preferably 1 to 12 carbon atoms and containing, as a hetero atom, for example, a nitrogen atom, an oxygen atom, or a sulfur atom, and specific examples include imidazolyl, pyridyl, quinolyl, furyl, thienyl, piperidyl, morpholino, benzoxazolyl, benzimidazolyl, and benzthiazolyl); and a silyl group (having preferably 3 to 40, more preferably 3 to 30, or particularly preferably 3 to 24 carbon atoms, such as trimethylsilyl or triphenylsilyl). Each of those substituents may be additionally substituted.

The another object of the present invention relates to use of the compounds, which are as described in the above contents, in the organic semiconductor devices, in particular, organic field-effect transistors OFETs.

The another object of the present invention relates to the organic semiconductor device, in particular, organic field-effect transistors OFETs, wherein at least one layer contains the compounds, which are as described in the above contents.

The organic semiconductor device can be any conventional organic semiconductor device used in the field, wherein it contains one layer contains the compounds, which are as described in the above contents.

A method of producing the compounds of the present invention is described.

The method of producing the compounds represented by the general formula (I) of the present invention is not particularly limited, and the derivative has only to be produced by a known method.

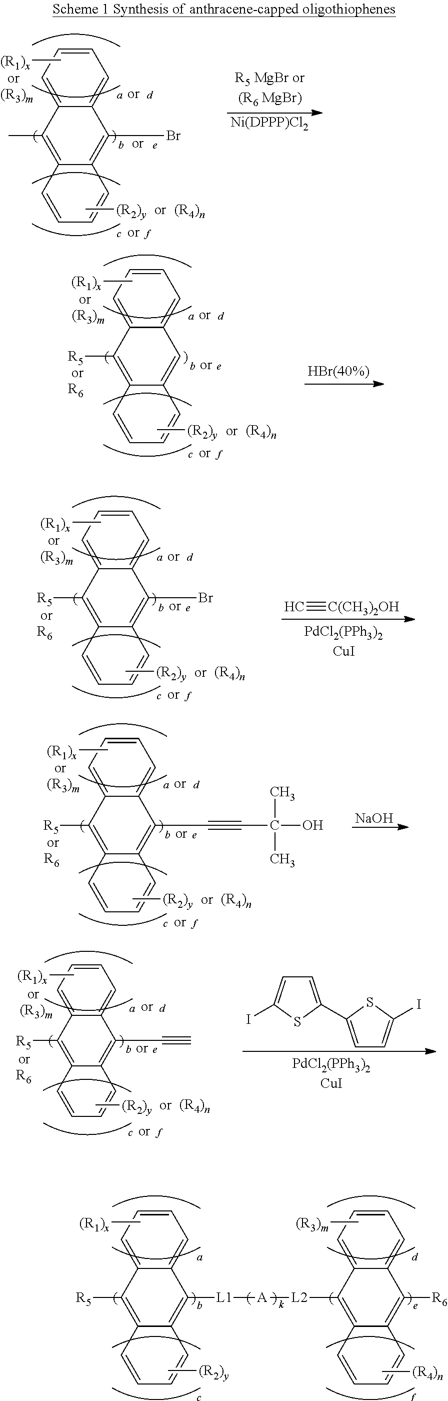

wherein, the definitions of L1, L2, A, R¹ to R⁶, a, b, c, d, e, f, k, x, y, m and n are same as the above or any other groups that can obtain final products.

### DESCRIPTION OF DRAWINGS

FIG. 1 schematically illustrates MALDI-TOF of ATTA (5,5′-bis(9-ethynylanthracenyl)-2,2′-bithiophene).

FIG. 2 schematically illustrates UV-Vis absorption spectrum of ATTA (5,5′-bis(9-ethynylanthracenyl)-2,2′-bithiophene) in chlorobenzene solution. The absorption peak located at 390 nm. The optical bandgap of ATTA estimated from the onset absorption is 2.86 eV.

FIG. 3 schematically illustrates thermal gravimetric analysis of ATTA (5,5′-bis(9-ethynylanthracenyl)-2,2′-bithiophene) at a heating rate of 10° C./min under nitrogen.

The thermal property of ATTA was characterized through thermal gravimetric analysis (TGA), as shown in FIG. 3. The onset decomposition temperature of ATTA was 265° C.

FIG. 4 schematically illustrates cyclic voltammogram of ATTA (5,5′-bis(9-ethynylanthracenyl)-2,2′-bithiophene).

Cyclic voltammogram of ATTA was performed in THF solutions with tetrabutlyammonium hexafluorophosphate (Bu₄NPF₆) as electrolyte, Ag/AgCl as reference electrode. Using ferrocene as reference, the HOMO energy levels of ATTA was calculated as −5.42 eV.

FIG. 5 schematically illustrates MALDI-TOF of C₁₂ATTA (5,5′-bis((10-dodecylanthracen-9-yl)ethynyl)-2,2′-bithiophene).

FIG. 6 schematically illustrates UV-Vis absorption spectra of C₁₂ATTA (5,5′-bis((10-dodecylanthracen-9-yl)ethynyl)-2,2′-bithiophene) in chlorobenzene solutions. The absorption peak located at 468 nm. The optical bandgap of C₁₂ATTA estimated from the onset absorption is 2.36 eV.

FIG. 7 schematically illustrates TGA curve of C₁₂ATTA (5,5′-bis((10-dodecylanthracen-9-yl)ethynyl)-2,2′-bithiophene).

FIG. 8 schematically illustrates DSC curve of C₁₂ATTA (5,5′-bis((10-dodecylanthracen-9-yl)ethynyl)-2,2′-bithiophene).

The thermal property of C₁₂ATTA was characterized through thermal gravimetric analysis (TGA) and differential scanning calorimetry (DSC). The onset decomposition temperature of C₁₂ATTA was observed at 312° C. The DSC result revealed that the melting point of C₁₂ATTA was 162° C., and C₁₂ATTA also exhibited liquid crystal properties when the temperature was 134° C.

FIG. 9 schematically illustrates Cyclic voltammogram of C₁₂ATTA (5,5′-bis((10-dodecylanthracen-9-yl)ethynyl)-2,2′-bithiophene).

Cyclic voltammogram of C₁₂ATTA was performed in THF solutions with tetrabutlyammonium hexafluorophosphate (Bu₄NPF₆) as electrolyte, Ag/AgCl as reference electrode. Using ferrocene as reference, the HOMO energy levels of C₁₂ATTA was calculated as −5.40 eV.

FIG. 10 illustrates (a,b) AFM images of solution processed C₁₂ATTA thin films on bare Si/SiO₂ substrates without any thermal treatment; (c,d) AFM images of solution-processed C₁₂ATTA thin films on OTS-modified Si/SiO₂ substrate without any thermal treatment.

C₁₂ATTA films (80-100 nm) were spin-coated on Si/SiO₂ substrate from chlorobenzene solution (10 mg/ml) at 1500 rpm in room temperature. The AFM images of the films deposited on SiO₂ and OTS modified SiO₂ substrates were shown in FIG. 5. No matter the substrates were modified by OTS or not, very smooth, uniform films could be spin-coated on the substrates. It demonstrated weak substrate dependence of this compound.

FIG. 11 illustrates (a) Schematic image of bottom-gate, top-contact C₁₂ATTA thin film transistors The corresponding transfer characteristics of the C₁₂ATTA thin film OFETs on bare Si/SiO₂ substrate (b) and OTS-modified Si/SiO₂ substrate (c) measured in air at room temperature.

FIG. 12 illustrates SEM images of C₁₂ATTA self-assembled on SiO₂/Si substrate through drop-casting method from chlorobenzene solutions. (a) Scale bar is 10 μm; (b) Scale bar is 2 μm.

Crystals of C₁₂ATTA was grown on SiO₂/Si substrate through drop-casting method from chlorobenzene solution. A large amount of flake-like crystal was obtained on the substrate (FIG. 12).

FIG. 13 illustrates (a) Molecular structure of C₁₂ATTA; (b) SEM image of a representative C₁₂ATTA single crystal transistor; (c) Transfer and (d) output characteristics of the C₁₂ATTA crystal transistor. Crystals transistors were fabricated in situ by gluing Au films onto the flake-like crystal as the source and drain electrodes. FIG. 13 shows the SEM images and corresponding device characteristics of an individual crystal transistor. The device exhibited p-type transistor behavior with the mobility about 10⁻²-10⁻³ cm²/Vs.

### MODE FOR CARRYING OUT THE INVENTION

Hereinafter, the present invention is described in detail by way of synthesis examples.

### EXAMPLES

Synthesis Example 1: preparation of 5,5′-bis(9-ethynylanthracenyl) -2,2′-bithiophene

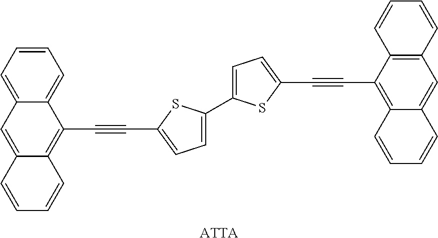 [SMILES: C(#Cc1c2ccccc2cc2ccccc12)c1ccc(-c2ccc(C#Cc3c4ccccc4cc4ccccc34)s2)s1 ; "ATTA"]

1.1 Synthesis

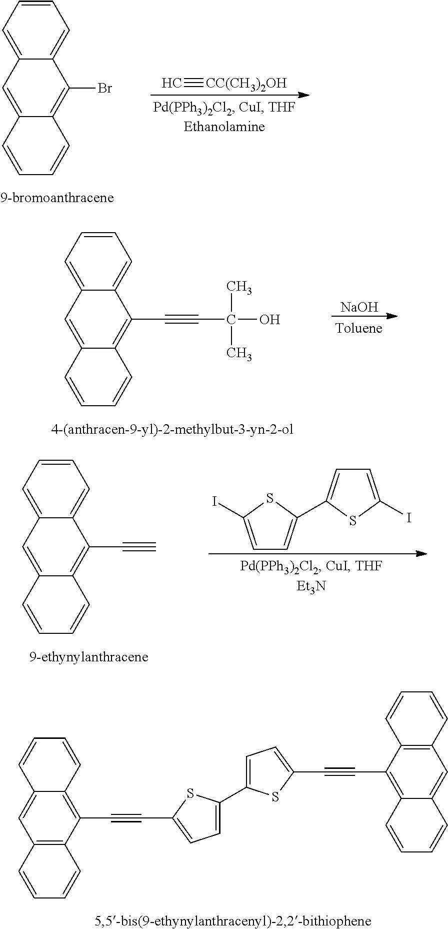

THF (50 mL) and 2M Ethanolamine (8 mL) were added successively to a mixture of 9-ethynylanthracene (1.01 g, 5 mmol), 5,5′-diiodo-2,2′-bithiophene (0.836 g, 2 mmol), CuI (46 mg, 0.24 mmol), and Pd(PPh₃)₂CL₂ (85 mg, 0.12 mmol) under nitrogen. The reaction mixture was stirred for 24 h at 65° C. Then the precipitate was collected by filtration and washed with water and methanol. The resulting precipitate was recrystallized from chlorobenzene to give red crystals of 5,5′-bis(9-ethynylanthracenyl)-2,2′-bithiophene, yield 46%. MS (TOF) m/z: 567 (M+1)⁺. ¹H-NMR (400 MHz, d-DMSO,ppm): 8.76 (s, 2H), 8.52 (d, 4H), 8.21 (d, 4H), 7.76 (m, 6H), 7.66 (m, 3H), 7.62 (m, 3H).

1.2 Characterization

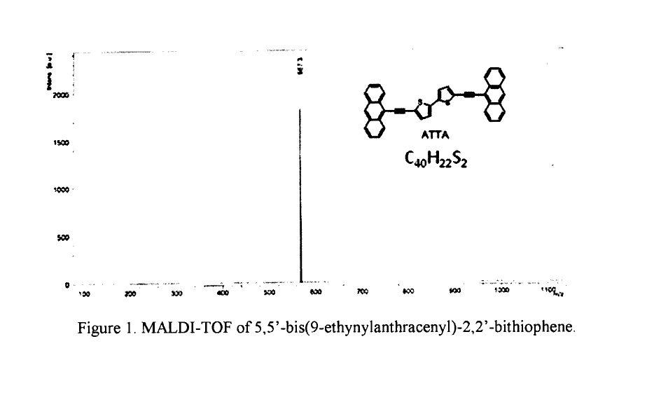

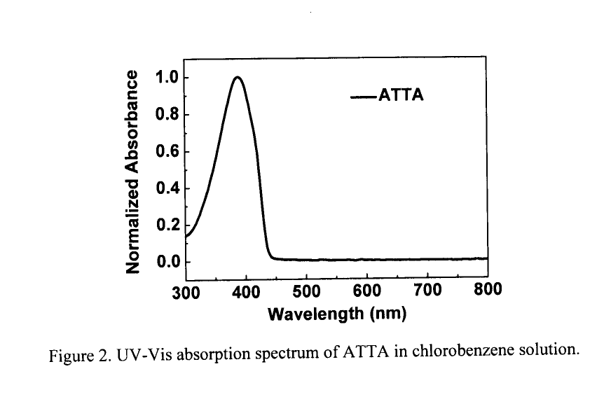

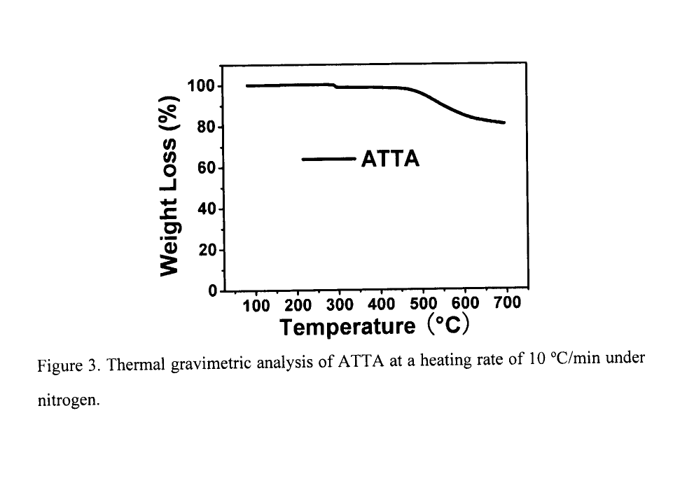

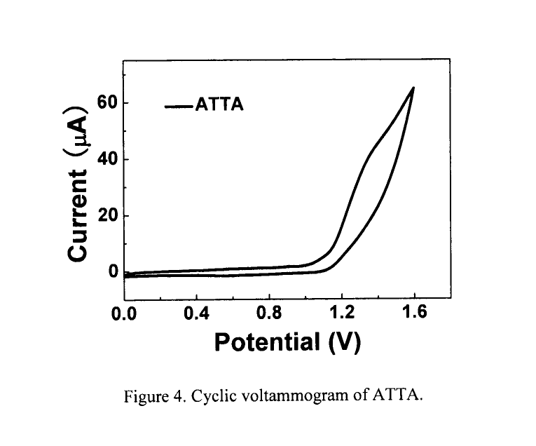

Mass spectrum of 5,5′-bis(9-ethynylanthracenyl)-2,2′-bithiophene see FIG. 1; the UV-Vis absorption of 5,5′ -bis(9-ethynylanthracenyl) -2,2′ -bithiophene see FIG. 2; Thermal gravimetric analysis of 5,5′-bis(9-ethynylanthracenyl)-2,2′-bithiophene see FIG. 3; the Cyclic voltammogram see FIG. 4.

FIG. 1 schematically illustrates MALDI-TOF of ATTA (5,5′-bis (9-ethynylanthracenyl)-2,2′-bithiophene).

FIG. 2 schematically illustrates UV-Vis absorption spectrum of ATTA (5,5′-bis(9-ethynylanthracenyl)-2,2′-bithiophene) in chlorobenzene solution. The absorption peak located at 390 nm. The optical bandgap of ATTA estimated from the onset absorption is 2.86 eV.

FIG. 3 schematically illustrates thermal gravimetric analysis of ATTA (5,5′-bis(9-ethynylanthracenyl)-2,2′-bithiophene) at a heating rate of 10° C./min under nitrogen.

The thermal property of ATTA was characterized through thermal gravimetric analysis (TGA), as shown in FIG. 3. The onset decomposition temperature of ATTA was 265° C.

FIG. 4 schematically illustrates Cyclic voltammogram of ATTA (5,5′-bis(9-ethynylanthracenyl)-2,2′-bithiophene). Cyclic voltammogram of ATTA was performed in THF solutions with tetrabutlyammonium hexafluorophosphate (Bu4NPF6) as electrolyte, Ag/AgCl as reference electrode. Using ferrocene as reference, the HOMO energy levels of ATTA was calculated as −5.42 eV.

Synthesis Example 2: preparation of 5,5′-bis((10-dodecylanthracen -9-yl)ethynyl)-2,2′-bithiophene

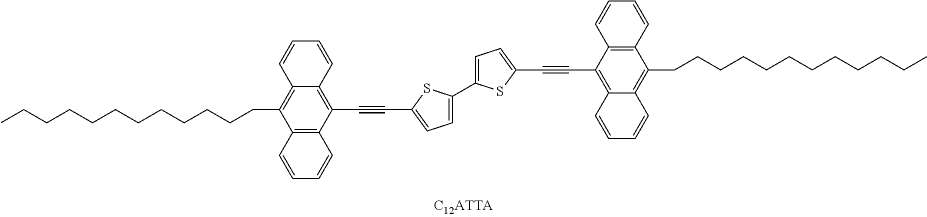 [SMILES: CCCCCCCCCCCCc1c2ccccc2c(C#Cc2ccc(-c3ccc(C#Cc4c5ccccc5c(CCCCCCCCCCCC)c5ccccc45)s3)s2)c2ccccc12]

2.1 Synthesis

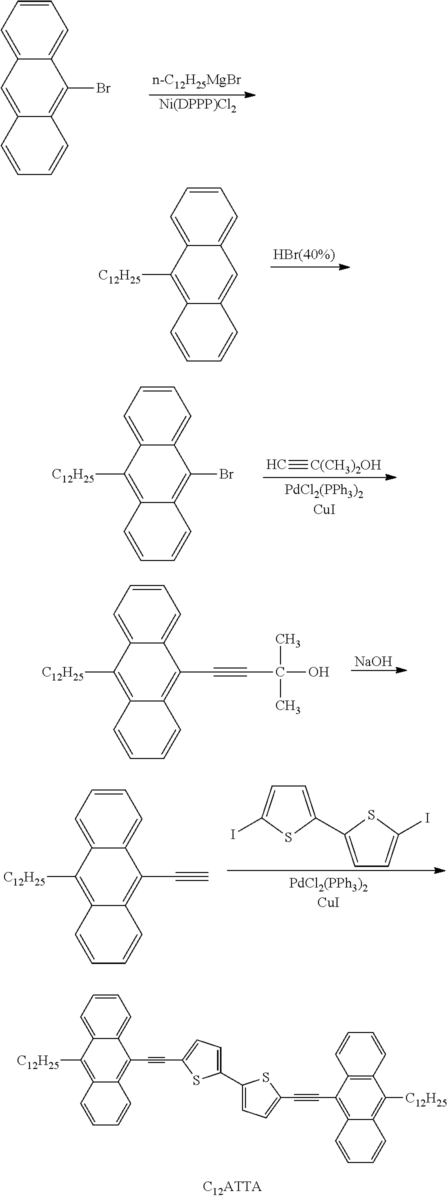

THF (50 mL) and 2 M Ethanolamine (0.4 mL) were added successively to a mixture of 5,5′-diiodo-2,2′-bithiophene (293 mg, 0.7 mmol), 9-dedocyl-10-ethylanthracene (600 mg, 1.62 mmol), CuI (18.5 mg), and Pd(PPh₃)₂CL₂ (34 mg) under nitrogen. The reaction mixture was stirred for 24 h at 65° C. under nitrogen protection. Then the solvent was removed under vacuum. The residue was purified by silica gel chromatography using petroleum/dichloromethane (4:1) as eluent to afford 5,5′-bis((10-dodecylanthracen-9-yl)ethynyl)-2,2′-bithiophene as red solid (470 mg, 74.4%). ¹h-NMR (400 MHz, CDCl₃, ppm): 8.66-8.64 (d, J=8.53 Hz, 4H), 8.32-8.30 (d, J=8.64 Hz, 4H), 7.64-7.55 (m, 8H), 7.40-7.39 (d, J=3.80 Hz, 2H), 7.24-7.23 (d, J=3.76 Hz, 2H), 3.64-3.60 (t, J=8.07 Hz, 4H), 1.84-1.81 (m, 4H), 1.61-1.58 (m, 4H), 1.42-1.27 (m, 32H), 0.90-0.87 (m, 6H). MS (TOF) m/z: 902.8 (calcd. for C₆₄H₇₀S₂: 902.5).

2.2 Characterization

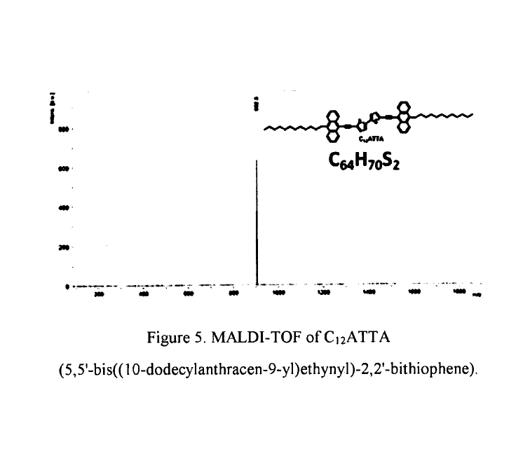

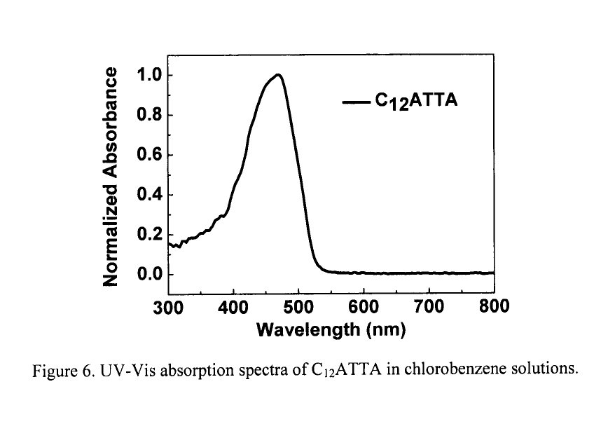

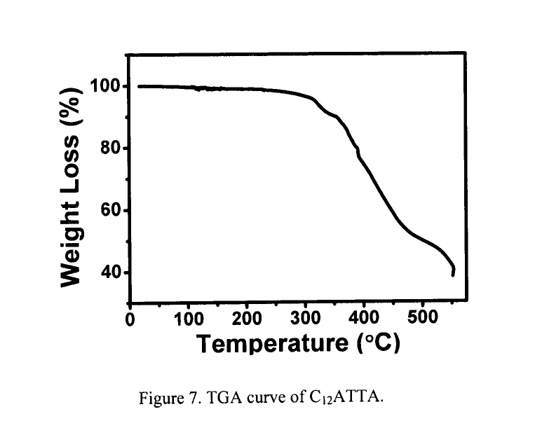

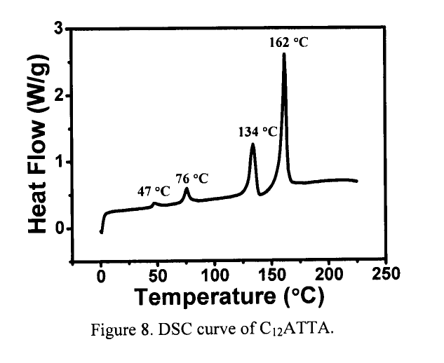

Mass spectrum of 5,5′-bis((10-dodecylanthracen-9-yl)ethynyl) -2,2′-bithiophene see FIG. 5; the UV-Vis absorption of 5,5′-bis ((10-dodecylanthracen-9-yl)ethynyl)-2,2′-bithiophene see FIG. 6; Thermal gravimetric analysis of 5,5′-bis((10-dodecylanthracen-9-yl) ethynyl)-2,2′-bithiophene see FIG. 7; the Cyclic voltammogram see FIG. 8.

FIG. 5 schematically illustrates MALDI-TOF of C₁₂ATTA (5,5′-bis((10-dodecylanthracen-9-yl)ethynyl)-2,2′-bithiophene).

FIG. 6 schematically illustrates UV-Vis absorption spectra of C₁₂ATTA (5,5′-bis((10-dodecylanthracen-9-yl)ethynyl)-2,2′-bithiophene) in chlorobenzene solutions. The absorption peak located at 468 nm. The optical bandgap of C₁₂ATTA estimated from the onset absorption is 2.36 eV.

FIG. 7 schematically illustrates TGA curve of C₁₂ATTA (5,5′-bis((10-dodecylanthracen-9-yl)ethynyl)-2,2′-bithiophene).

FIG. 8 schematically illustrates DSC curve of C₁₂ATTA (5,5′-bis((10-dodecylanthracen-9-yl)ethynyl)-2,2′-bithiophene).

The thermal property of C₁₂ATTA was characterized through thermal gravimetric analysis (TGA) and differential scanning calorimetry (DSC). The onset decomposition temperature of C₁₂ATTA was observed at 312° C. The DSC result revealed that the melting point of C₁₂ATTA was 162° C., and C₁₂ATTA also exhibited liquid crystal properties when the temperature was 134° C.

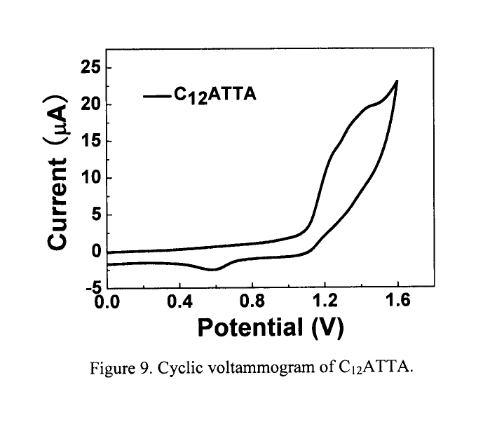

FIG. 9 schematically illustrates Cyclic voltammogram of C₁₂ATTA (5,5′-bis((10-dodecylanthracen-9-yl)ethynyl)-2,2′-bithiophene).

Cyclic voltammogram of C₁₂ATTA was performed in THF solutions with tetrabutlyammonium hexafluorophosphate (Bu₄NPF₆) as electrolyte, Ag/AgCl as reference electrode. Using ferrocene as reference, the HOMO energy levels of C₁₂ATTA was calculated as −5.40 eV.

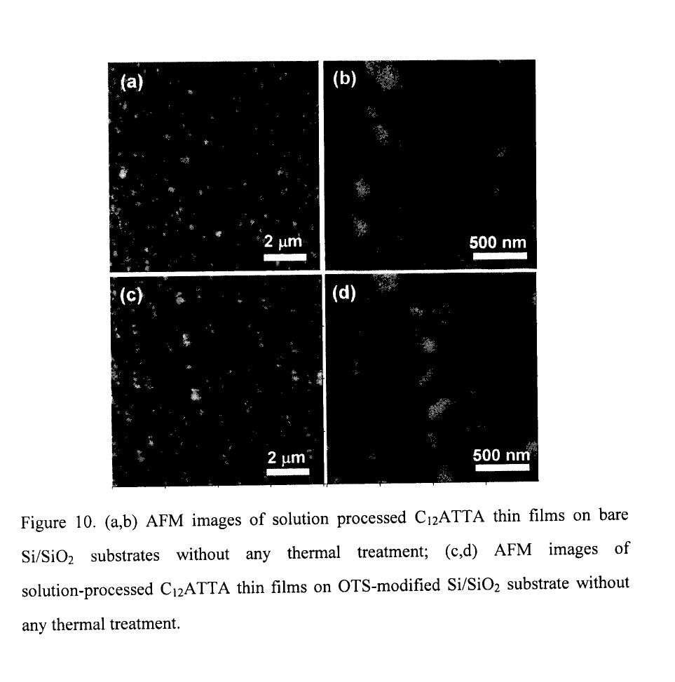

FIG. 10 illustrates (a,b) AFM images of solution processed C₁₂ATTA thin films on bare Si/SiO2 substrates without any thermal treatment; (c,d) AFM images of solution-processed C₁₂ATTA thin films on OTS-modified Si/SiO2 substrate without any thermal treatment. C₁₂ATTA films (80-100 nm) were spin-coated on Si/SiO₂ substrate from chlorobenzene solution (10 mg/ml) at 1500 rpm in room temperature. The AFM images of the films deposited on SiO₂ and OTS modified SiO₂ substrates were shown in FIG. 5. No matter the substrates were modified by OTS or not, very smooth, uniform films could be spin-coated on the substrates. It demonstrated weak substrate dependence of this compound.

Device Example 3:

1. Device fabrication

Electrodes of Au (25 nm) were vacuum-deposited on C₁₂ATTA films with channel length and width at 100 μmm and 4.82 mm, respectively. Current-voltage (I-V) characteristics were recorded by a Keithley 4200 SCS with a Micromanipulator 6150 probe station in a clean and shielded box at room temperature in air. The morphologies of the films were performed by an Nanoscope III atomic force microscopy (AFM) (USA) in a tapping model.

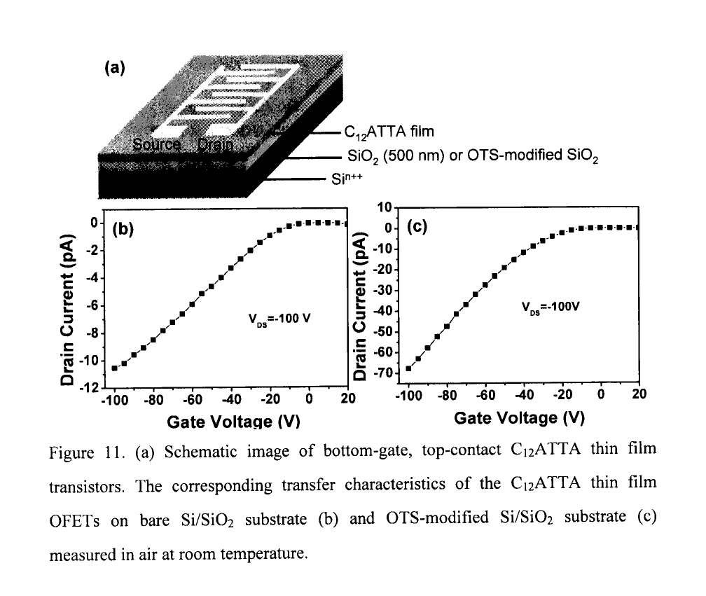

The transfer characteristics of the devices based on SiO₂ and OTS modified SiO₂ substrates were shown in FIG. 11. Both devices exhibited ideal transfer characteristics, which further confirmed the weak substrate dependence of the device performance, which was highly accorded with the AFM results of the films on SiO₂ and OTS modified substrates.

2. Drop-Casted Crystals

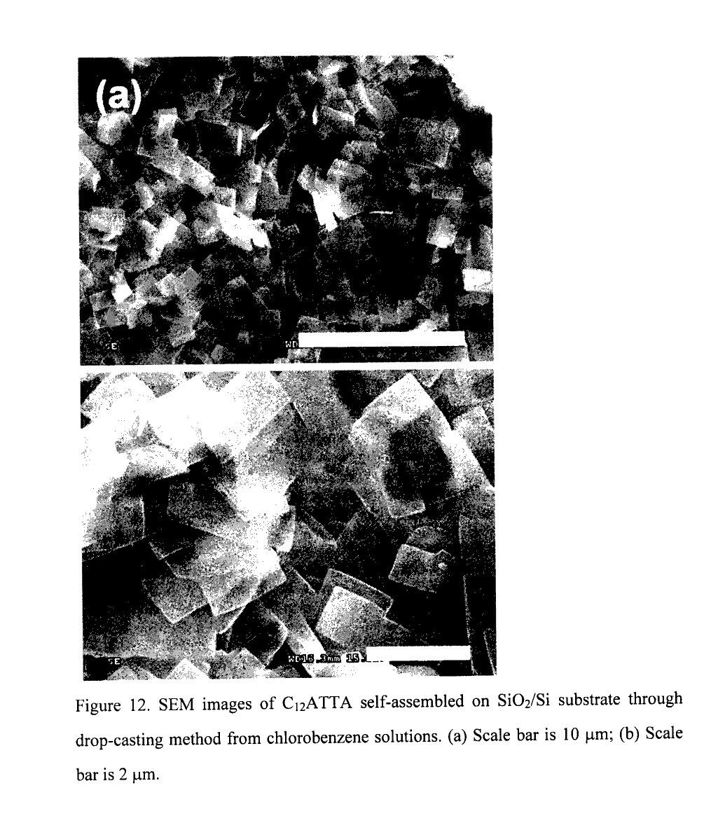

Crystals of C₁₂ATTA was grown on SiO₂/Si substrate through drop-casting method from chlorobenzene solution. A large amount of flake-like crystal was obtained on the substrate (FIG. 12).

3. Single Crystal Transistor

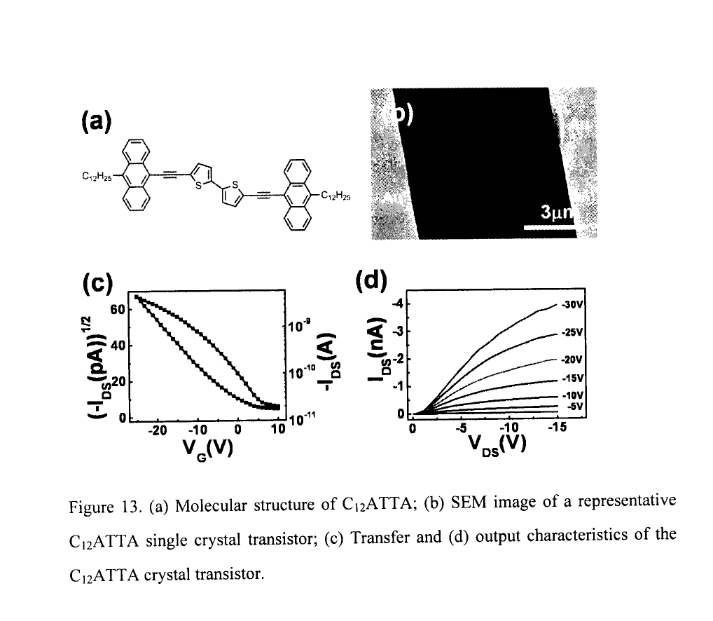

Crystals transistors were fabricated in situ by gluing Au films onto the flake-like crystal as the source and drain electrodes. FIG. 13 shows the SEM images and corresponding device characteristics of an individual crystal transistor. The device exhibited p-type transistor behavior with the mobility about 10⁻²-10⁻³ cm²/Vs.

1. A compound having the following formula (1): 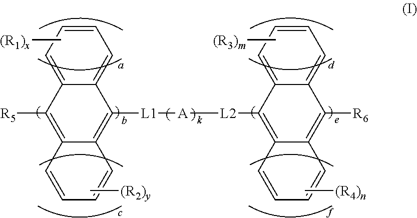
Wherein, R1, R2, R3, R4, R5 and R6, identical or different from each other, each independently represent
a hydrogen atom,
a substituted or unsubstituted alkyl group having 1 to 50 carbon atoms,
a substituted or unsubstituted alkoxyl group having 1 to 50 carbon atoms,
a substituted or unsubstituted aryl group having 6 to 50 carbon atoms,
a substituted or unsubstituted cycloalkyl group having 3 to 50 carbon atoms,
a substituted or unsubstituted heteroaromatic group having 5 to 50 carbon atoms, containing at least one heteroatom Z which is selected from the group consisting of the elements of IIIA, IVA, VA or VIA in periodic table of elements,
a substituted or unsubstituted heterocyclic having 5 to 50 carbon atoms,
a substituted or unsubstituted aralkyl group, wherein the aryl portion has 6 to 50 carbon atoms and the alkyl portion has 1 to 50 carbon atoms,
a substituted or unsubstituted aryloxy group having 5 to 50 carbon atoms;
L1, L2, identical or different, represent single bond, double bond or triple bond,
A represents a heteroaromatic group, containing at least one heteroatom W which is selected from the group consisting of the elements of IIIA, IVA, VA or VIA in periodic table of elements;
a, c, d, f, identical or different from each other, represent an integer of 1-10;
b, e, identical or different from each other, represent an integer of 1-5;
k represents an integer of 1-5;
x, y, m, n, identical or different, represent an integer of between 0 and the number of rings, for example, 1-10;
Provided that, when b is 1, R5- is hydrogen, e is 1, -R6 is hydrogen, all of a, c, d and f equal to 1, A is not

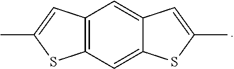

2. The compound according to claim 1, wherein the elements of IIIA, IVA, VA or VIA in periodic table of elements are selected from B, Si, Sn, N, O, S and Se.

3. The compounds according to claim 1, wherein R1, R2, R3, R4, R5 and R6, identical or different from each other, each independently represent
a hydrogen atom,
a substituted or unsubstituted alkyl group having 1 to 6 carbon atoms,
a substituted or unsubstituted alkoxyl group having 1 to 6 carbon atoms,
a substituted or unsubstituted aryl group having 6 to 8 carbon atoms,
a substituted or unsubstituted cycloalkyl group having 3 to 8 carbon atoms,
a substituted or unsubstituted heteroaromatic group having 5 to 8 carbon atoms, containing at least one heteroatom M which is selected from the group consisting of B, Si, Sn, N, O, S, Se,
a substituted or unsubstituted heterocyclic having 5 to 10 carbon atoms,
a substituted or unsubstituted aralkyl group, wherein the aryl portion has 6 to 8 carbon atoms and the alkyl portion has 1 to 6 carbon atoms,
a substituted or unsubstituted aryloxy group having 6 to 8 carbon atoms.

4. The compounds according to claim 1, wherein A represents a heteroaromatic group having 5-10 ring atoms.

5. The compounds according to claim 1, wherein R5 and R6 are hydrogen atom.

6. The compounds according to claim 1, wherein b and e represent 1 or 2.

7. The compounds according to claim I, wherein k equal to 1 or 2.

8. The compounds according to claim 1, wherein L1 and L2, identical or different from each other, represent triple bond.

9. The compounds according to claim 1, wherein W and Z, identical or different from each other, represent S or Se.

10. The compounds according to claim 1, wherein the substituent substituting for each group in each of the general formula (1) comprises include:
an alkyl group,
an alkenyl group,
an alkynyl group,
an aryl group,
an amino group,
an alkoxy group,
an aryloxy group,
an heteroaryloxy group,
an alkoxycarbonyl group,
an aryloxycarbonyl group,
an acyloxy group,
an acylamino group,
an alkoxycarbonylamino group,
an aryloxycarbonylamino group,
a sulfonylamino group,
a sulfamoyl group,
a carbamoyl group,
an alkylthio group,
an arylthio group,
a heteroarylthio group,
a sulfonyl group,
a sulfinyl group,
a ureido group,
a phosphoric acid amide group;
a hydroxyl group;
a mercapto group;
a halogen atom,
a cyano group;
a sulfo group;
a carboxyl group;
a nitro group;
a hydroxamic acid group;
a sulfino group; a hydrazino group;
an imino group; a heterocyclic group containing, as a hetero atom, a nitrogen atom, an oxygen atom, or a sulfur atom,
a silyl group.

11. The compounds according to 1, represented by:

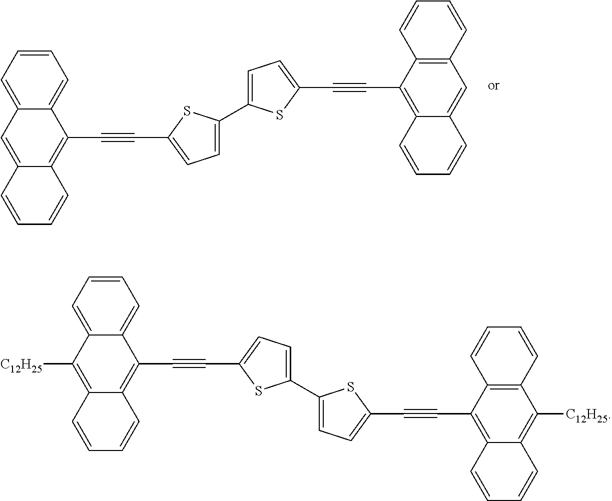

12. The process for preparing the compounds represented by the general formula (I) according to claim 1, comprising the following steps:

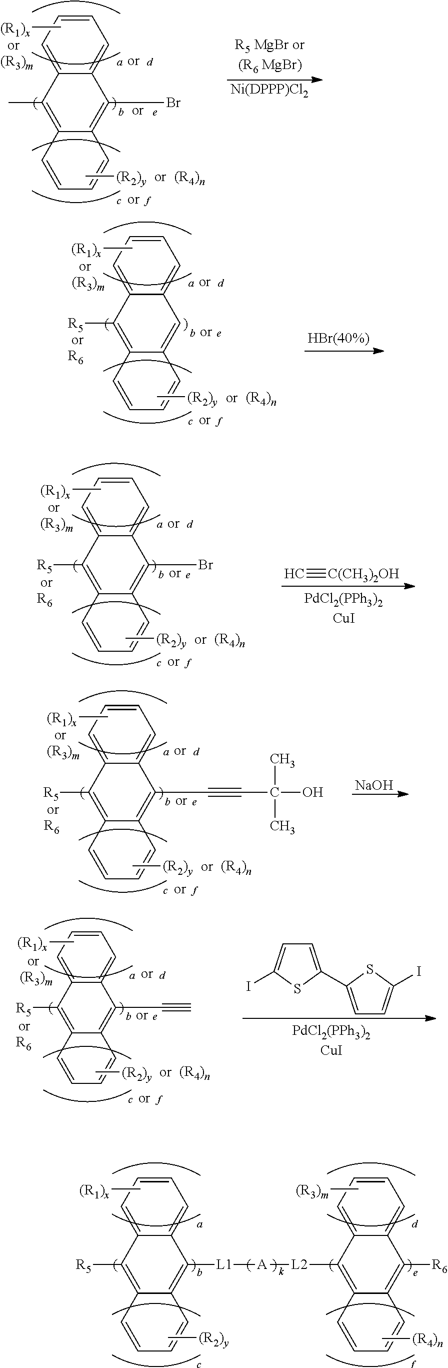

13. A method comprising incorporating the compound of claim 1 in an organic semiconductor devices.

14. An organic semiconductor device, comprising at least one layer comprising the compound according to claim 1.

15. The method of claim 13, wherein the organic semiconducting device is an organic field-effect transistor.

16. The organic semiconductor device of claim 14, wherein the organic semiconducting device is an organic field-effect transistor.

17. The compound according to claim 10, wherein the substituent substituting for each group in each of the general formula (1) comprises:
an alkyl group selected from the group consisting of methyl, ethyl, isopropyl, t-butyl, n-octyl, n-decyl, and n-hexadecyl;
a cycloalkyl group selected from the group consisting of cyclopropyl, cyclopentyl, and cyclohexyl;
an alkenyl group selected from the group consisting of vinyl, allyl, 2-butenyl, and 3-pentenyl;
an alkynyl group selected from the group consisting of propargyl and 3-pentynyl,
an aryl group selected from the group consisting of phenyl, p-methylphenyl, naphthyl, and anthranyl;
an amino group selected from the group consisting of amino, methylamino, dimethylamino, diethylamino, dibenzylamino, diphenylamino, and ditolylamino;
an alkoxy group selected from the group consisting of methoxy, ethoxy, butoxy, and 2-ethylhexyloxy;
an aryloxy group selected from the group consisting of phenyloxy, 1-naphthyloxy, and 2-naphthyloxy;
an heteroaryloxy group selected from the group consisting of pyridyloxy, pyrazyloxy, pyrimidyloxy, and quinolyloxy;
an acyl group selected from the group consisting of acetyl, benzoyl, formyl, and pivaloyl;
an alkoxycarbonyl group selected from the group consisting of methoxycarbonyl and ethoxycarbonyl;
an aryloxycarbonyl group selected from the group consisting of phenyloxycarbonyl;
an acyloxy group selected from the group consisting of acetoxy and benzoyloxy;
an acylamino group selected from the group consisting of acetylamino and benzoylamino;
an alkoxycarbonylamino group selected from the group consisting of methoxycarbonylamino;
an aryloxycarbonylamino group selected from the group consisting of phenyloxycarbonylamino;
a sulfonylamino group selected from the group consisting of methanesulfonylamino and benzenesulfonylamino;
a sulfamoyl group selected from the group consisting of sulfamoyl, methylsulfamoyl, dimethylsulfamoyl, and phenylsulfamoyl;
a carbamoyl group selected from the group consisting of carbamoyl, methylcarbamoyl, diethylcarbamoyl, and phenylcarbamoyl;
an alkylthio group selected from the group consisting of methylthio and ethylthio;
an arylthio group selected from the group consisting of phenylthio;
a heteroarylthio group selected from the group consisting of pyridylthio, 2-benzimizolylthio, 2-benzoxazolylthio, and 2-benzthiazolylthio;
a sulfonyl group selected from the group consisting of mesyl and tosyl;
a sulfinyl group selected from the group consisting of methanesulfinyl and benzenesulfinyl;
a ureido group selected from the group consisting of ureido, methylureido, and phenylureido;
a phosphoric acid amide group;
a hydroxyl group;
a mercapto group;
a halogen atom selected from the group consisting of a fluorine atom, a chlorine atom, a bromine atom, and an iodine atom;
a cyano group;
a sulfo group;
a carboxyl group;
a nitro group;
a hydroxamic acid group;
a sulfino group;
a hydrazino group;
an imino group;
a heterocyclic group selected from the group consisting of imidazolyl, pyridyl, quinolyl, furyl, thienyl, piperidyl, morpholino, benzoxazolyl, benzimidazolyl, and benzthiazolyl; or
a silyl group selected from the group consisting of trimethylsilyl and triphenylsilyl.

18. The compound according to claim 1, wherein A is thiophene.

19. The compound according to claim 18, wherein k is 2.

20. The compound according to claim 19, wherein L1 and L2 are each triple bonds.
